(19) United States
(12) Patent Application Publication
(10) Pub. No.: US 2025/0372479 A1
(43) Pub. Date: Dec. 4, 2025

(54) PACKAGE COMPRISING AN INTEGRATED DEVICE, A SUBSTRATE AND A HEAT SINK

(71) Applicant: QUALCOMM Incorporated, San Diego, CA (US)

(72) Inventors: Zhijie WANG, San Diego, CA (US); Rajneesh KUMAR, San Diego, CA (US); Manuel ALDRETE, Encinitas, CA (US); Sang-Jae LEE, San Diego, CA (US); Seongho KIM, San Diego, CA (US)

(21) Appl. No.: 18/680,740

(22) Filed: May 31, 2024

(51) Int. Cl. H01L 23/373; H01L 23/31; H01L 23/495; H01L 23/498

(52) U.S. Cl. CPC H01L 23/3736; H01L 23/3157; H01L 23/49568; H01L 23/49816

(57) ABSTRACT

A package comprising a first substrate; an integrated device coupled to the substrate; a second substrate coupled to the first substrate through at least a plurality of solder interconnects, wherein the second substrate is located over a portion of the integrated device; and a heat sink coupled to a back side of the integrated device through a thermal interface material, wherein the heat sink is located over another portion of the integrated device, wherein the heat sink is located laterally to the second substrate.

### FIELD

Various features relate to packages with substrates and integrated devices.

### BACKGROUND

A package may include a substrate and integrated devices. These components are coupled together to provide a package that may perform various electrical functions. There is an ongoing need to provide better performing packages. Moreover, there is also an ongoing need to reduce the overall size of the packages.

### SUMMARY

Various features relate to packages with substrates and integrated devices.

One example provides a package comprising a first substrate; an integrated device coupled to the first substrate; a second substrate coupled to the first substrate through at least a plurality of solder interconnects, wherein the second substrate is located over a portion of the integrated device; and a heat sink coupled to a back side of the integrated device through a thermal interface material, wherein the heat sink is located over another portion of the integrated device, wherein the heat sink is located laterally to the second substrate.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary cross sectional profile view of a package that includes a first substrate, a second substrate, an integrated device and a heat sink.

FIG. 2 illustrates an exemplary cross sectional profile view of a package that includes a first substrate, a second substrate, an integrated device and a heat sink.

FIG. 3 illustrates an exemplary plan view of a package that includes a first substrate, a second substrate, an integrated device and a heat sink.

FIGS. 4A-4D illustrate an exemplary sequence for fabricating a package that includes a first substrate, a second substrate, an integrated device and a heat sink.

FIG. 5 illustrates an exemplary sequence for fabricating a package that includes a first substrate, a second substrate, an integrated device and a heat sink.

FIG. 6 illustrates an exemplary flow chart of a method for fabricating a package that includes a first substrate, a second substrate, an integrated device and a heat sink.

FIGS. 7A-7B illustrate an exemplary sequence for fabricating a substrate.

FIG. 8 illustrates an exemplary flow chart of a method for fabricating a substrate.

FIG. 9 illustrates an exemplary flow chart of a method for fabricating a package that includes a first substrate, a second substrate, an integrated device and a heat sink.

FIG. 10 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising a first substrate; an integrated device coupled to the first substrate; a second substrate coupled to the first substrate through at least a plurality of solder interconnects, wherein the second substrate is located over a portion of the integrated device; and a heat sink coupled to a back side of the integrated device through a thermal interface material, wherein the heat sink is located over another portion of the integrated device, wherein the heat sink is located laterally to the second substrate. In some implementations, the configuration of the package helps improve thermal performance (e.g., improve heat dissipation) of the package, while also minimizing, reducing and/or keeping the lateral size and/or footprint of the package as small as possible.

### Exemplary Package Comprising a Substrate and a Heat Sink Coupled to Back Side of an Integrated Device

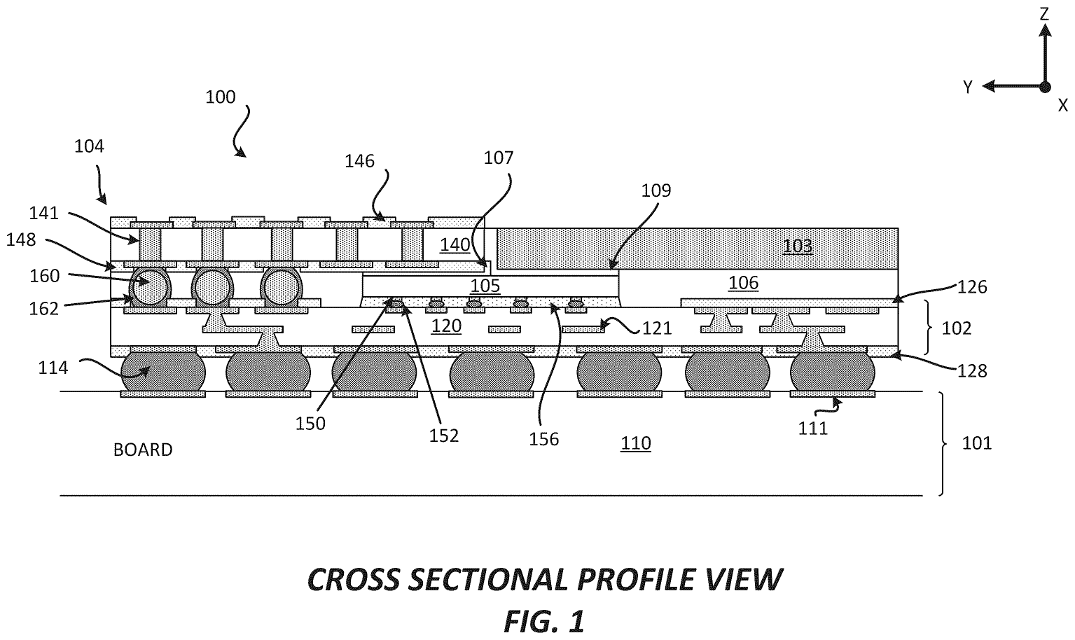

FIG. 1 illustrates a cross sectional profile view of a package 100 that includes a substrate and a heat sink coupled to a back side of an integrated device. The package 100 may be implemented as part of a package on package (PoP). The package 100 is coupled to a board 101 through a plurality of solder interconnects 114. The board 101 includes at least one board dielectric layer 110 and a plurality of board interconnects 112. The board 101 may include a printed circuit board (PCB).

The package 100 includes a substrate 102, an integrated device 105, a substrate 104, a heat sink 103, an encapsulation layer 106, a plurality of ball interconnects 160 and a plurality of solder interconnects 162. The substrate 102 may be a first substrate. The substrate 104 may be a second substrate.

The substrate 102 includes at least one dielectric layer 120, a plurality of interconnects 121, a solder resist layer 126 and a solder resist layer 128. The integrated device 105 may be coupled to a first surface of the substrate 102 through a plurality of pillar interconnects 150 and/or a plurality of solder interconnects 152. For example, the integrated device 105 may be coupled to interconnects from the plurality of interconnects 121 of the substrate 102, through a plurality of pillar interconnects 150 and a plurality of solder interconnects 152. An underfill 156 may be located vertically between the integrated device 105 and the substrate 102. The underfill 156 may include a composite material comprising an epoxy polymer with filler.

The substrate 104 may be an interposer (e.g., package interposer). The substrate 104 may include a dielectric layer 140 (e.g., interposer dielectric layer), a plurality of interconnects 141 (e.g., interposer interconnects), a solder resist layer 146 and a solder resist layer 148. The dielectric layer 140 (e.g., interposer dielectric layer) may include silicon, glass or an organic dielectric layer. The substrate 104 has a lateral size that is less than the lateral size of the substrate 102. For example, if the substrate 102 has a width W1, the substrate 104 may have a width W2 that is less than W1. In some implementations, the lateral size of the substrate 104 may be about 50% of the lateral size (x by y size) of the substrate 102. However, the lateral size of the substrate 104 relative to the lateral size of the substrate 102 may be more or less than 50% (e.g., 30%-70%).

The substrate 104 is coupled to the substrate 102 through the plurality of ball interconnects 160 and/or the plurality of solder interconnects 162. The plurality of ball interconnects 160 may include a plurality of copper balls. The plurality of ball interconnects 160 and/or the plurality of solder interconnects 162 may be coupled to (i) the plurality of interconnects 121 of the substrate 102 and (ii) the plurality of interconnects 141 of the substrate 104. The plurality of ball interconnects 160 and/or the plurality of solder interconnects 162 may be located vertically between the substrate 102 and the substrate 104. The substrate 104 may be coupled to a back side of the integrated device 105. For example, the substrate 104 may be coupled to the back side of the integrated device 105 through an adhesive 107. In some implementations, instead of and/or in conjunction with the adhesive 107, the substrate 104 may be coupled to the back side of the integrated device 105 through a thermal interface material (TIM). A portion of the substrate 104 may vertically overlap with a portion of the integrated device 105. For example, a portion of the substrate 104 may vertically overlap with some portion (e.g., some part) of the integrated device 105, but may not vertically overlap with another portion of the integrated device 105.

The heat sink 103 is coupled to the back side of the integrated device 105. For example, the heat sink 103 may be coupled to the back side of the integrated device 105 through a thermal interface material (TIM) 109. In some implementations, the substrate 104 may be coupled to the back side of the integrated device 105 through the thermal interface material (TIM) 109. The heat sink 103 is located laterally to the substrate 102. The heat sink 103 vertically overlaps with a first portion of the integrated device 105 (e.g., the heat sink 103 vertically overlaps with a first portion of the integrated device 105, but not all portions of the integrated device 105). The substrate 104 vertically overlaps with a second portion of the integrated device 105 (e.g., the substrate 104 vertically overlaps with a second portion of the integrated device 105, but not all portions of the integrated device 105). The thermal interface material (TIM) 109 and/or the adhesive 107 may be located between the substrate 104 and the heat sink 103. The heat sink 103 may be a metal slug that has a relatively high coefficient of thermal conductivity. The heat sink 103 may include copper. Different implementations of the package 100 may include a heat sink 103 with different lateral sizes. In some implementations, the lateral size of the heat sink 103 may be about 50% of the lateral size (x by y size) of the substrate 102. However, the lateral size of the heat sink 103 relative to the lateral size of the substrate 102 may be more or less than 50% (e.g., 30%-70%). The heat sink 103 may include several heat sinks, or one continuous and/or contiguous heat sink block (e.g., unibody heat sink block). The heat sink 103 may include a composite material.

The encapsulation layer 106 is located vertically between the substrate 102 and the heat sink 103. The encapsulation layer 106 is coupled to and touching the substrate 102 and the heat sink 103. The encapsulation layer 106 is located between the substrate 102 and the substrate 104. The encapsulation layer 106 is coupled to and touching the substrate 102 and the substrate 104. The encapsulation layer 106 may at least partially encapsulate the integrated device 105, the plurality of ball interconnects 160 and/or the plurality of solder interconnects 162. The encapsulation layer 106 may include a mold, a resin, an epoxy and/or a filler. The encapsulation layer 106 may include a different material and/or a different composition from the underfill 156.

The configuration of the package 100 helps improve thermal performance (e.g., improve heat dissipation), while also minimizing, reducing and/or keeping the lateral size and/or footprint of the package 100 as small as possible. For example, placing the heat sink 103 to be closer to the integrated device 105, helps improve the thermal performance of the integrated device 105.

In some implementations, an integrated device or a package may be coupled to the substrate 104. The integrated device (e.g., second integrated device, another integrated device) may be coupled to the substrate 104 through a plurality of solder interconnects. The second integrated device may be located laterally to the heat sink 103. Another package may be coupled to the substrate 104 through a plurality of solder interconnects.

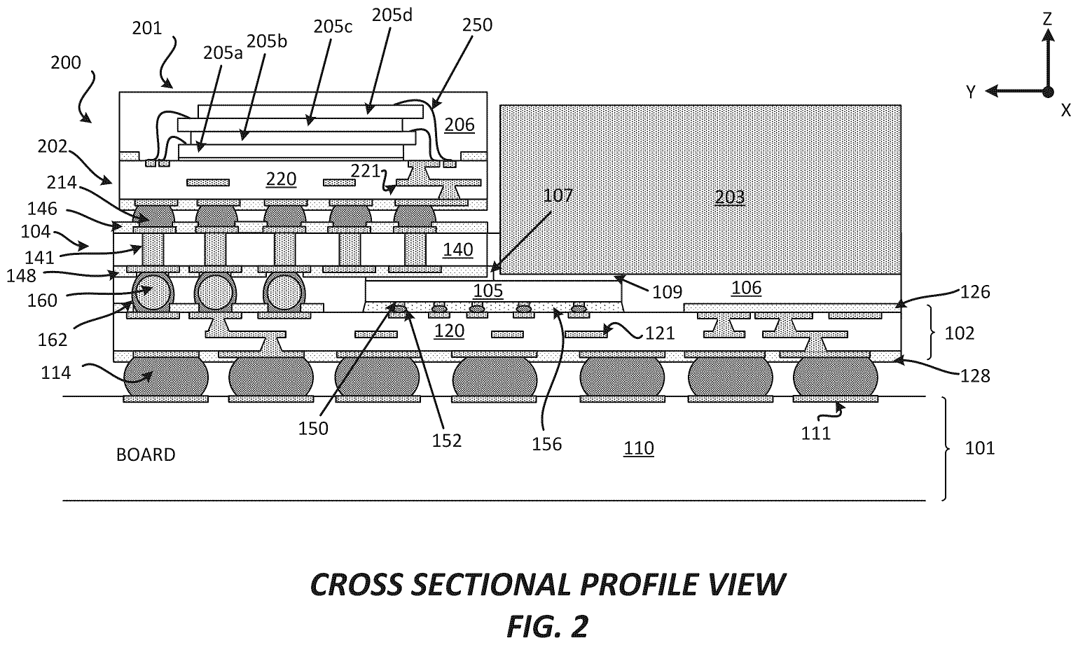

FIG. 2 illustrates a cross sectional profile view of a package 200 that includes a substrate and a heat sink coupled to a back side of an integrated device. The package 200 may be implemented as part of a package on package (POP). The package 200 is coupled to a board 101 through a plurality of solder interconnects 114. The package 200 is similar to the package 100 and may include components that are arranged in a similar manner as described for the package 100.

The package 200 includes a substrate 102, an integrated device 105, a substrate 104, a heat sink 203, an encapsulation layer 106, a plurality of ball interconnects 160, a plurality of solder interconnects 162 and a package 201. The substrate 102 may be a first substrate. The substrate 104 may be a second substrate. The substrate 104 may be an interposer (e.g., package interposer).

The integrated device 105 is coupled to the substrate 102 through a plurality of pillar interconnects 150 and/or a plurality of solder interconnects 152. The underfill 156 is located between the integrated device 105 and the substrate 102. The substrate 104 is coupled to the substrate 102 through the plurality of ball interconnects 160 and/or the plurality of solder interconnects 162. The substrate 104 is coupled to a portion of the back side of the integrated device 105 through an adhesive 107. In some implementations, the substrate 104 is coupled to a portion of the back side of the integrated device 105 through an adhesive 107 and/or a thermal interface material (TIM) 109. The heat sink 203 is coupled to another portion of the back side of the integrated device 105 through the thermal interface material (TIM) 109. The thermal interface material (TIM) 109 may include a different material from the adhesive 107. The adhesive 107 may include die attach film (DAF). In some implementations, the adhesive 107 may include a Henkel adhesive. In some implementations, the thermal interface material (TIM) 109 may include a Shin-Etsu thermal interface material. However, different implementations may use different materials for the adhesive 107 and/or the thermal interface material (TIM) 109. The heat sink 203 may be located laterally to the substrate 104. The heat sink 203 may be similar to the heat sink 103. However, the heat sink 203 may be thicker than the heat sink 103. The encapsulation layer 106 is located vertically between the substrate 102 and the heat sink 203. The encapsulation layer 106 is located vertically between the substrate 102 and the substrate 104 (e.g., interposer).

The package 201 includes a substrate 202, an integrated device 205a, an integrated device 205b, an integrated device 205c, an integrated device 205d and an encapsulation layer 206. The substrate 202 includes at least one dielectric layer 220 and a plurality of interconnects 221. The substrate 202 may be a package substrate. The integrated device 205a, the integrated device 205b, the integrated device 205c and the integrated device 205d may be a stack of integrated devices. The integrated device 205a, the integrated device 205b, the integrated device 205c and the integrated device 205d may each be a memory die (e.g., dynamic random access memory (DRAM) die). The integrated device 205a, the integrated device 205b, the integrated device 205c and/or the integrated device 205d may be configured to be electrically coupled to the substrate 202 through one or more wire bonds from a plurality of wire bonds 250. The encapsulation layer 206 is coupled to the substrate 202. The encapsulation layer 206 may at least partially encapsulate the integrated device 205a, the integrated device 205b, the integrated device 205c, the integrated device 205d and the plurality of wire bonds 250.

The package 201 is coupled to the substrate 104 through a plurality of solder interconnects 214. For example, the substrate 202 may be coupled to the substrate 104 through the plurality of solder interconnects 214. The package 201 may be located laterally (e.g., at least partially laterally) to the heat sink 203.

The configuration of the package 200 helps improve thermal performance (e.g., improve heat dissipation), while also minimizing, reducing and/or keeping the lateral size and/or footprint of the package 200 as small as possible. For example, placing the heat sink 203 to be closer to the integrated device 105, helps improve the thermal performance of the integrated device 105.

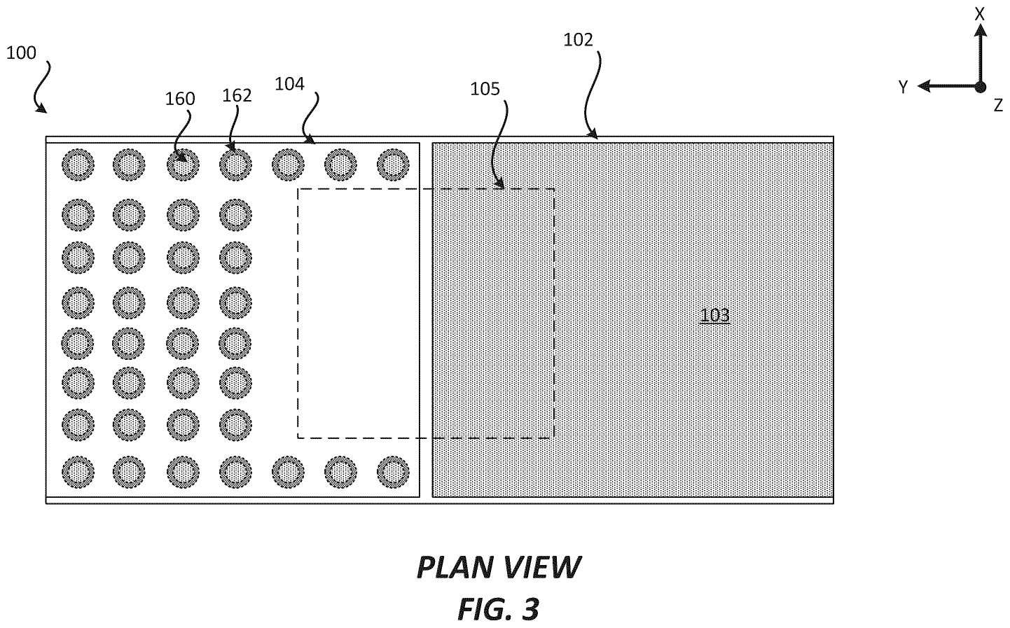

FIG. 3 illustrates an exemplary plan view of the package 100. The package 100 includes the substrate 102, the substrate 104, the integrated device 105, the heat sink 103, the plurality of ball interconnects 160 and the plurality of solder interconnects 162. FIG. 3 illustrates that (i) the lateral size and/or lateral dimension of the substrate 104 is about 50% of the lateral size and/or the lateral dimension of the substrate, and (ii) the lateral size and/or lateral dimension of the heat sink 103 is about 50% of the lateral size and/or lateral dimension of the substrate 102. The heat sink 103 vertically overlaps with a first portion of the integrated device 105 (e.g., the heat sink 103 vertically overlaps with a first portion of the integrated device 105, but not all portions of the integrated device 105). The substrate 104 vertically overlaps with a second portion of the integrated device 105 (e.g., the substrate 104 vertically overlaps with a second portion of the integrated device 105, but not all portions of the integrated device 105). It is noted that the size, the shape and/or the position of the substrate 104 and/or the heat sink 103 may vary with different implementations of the package. The plurality of ball interconnects 160 and the plurality of solder interconnects 162 are located laterally to the integrated device 105.

An integrated device (e.g., 105) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc.). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 103) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap with between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 100, 200) may be implemented in a radio frequency (RF) package. The RF package may be a radio frequency front end (RFFE) package. A package (e.g., 100) may be configured to provide Wireless Fidelity (WiFi) communication and/or cellular communication (e.g., 2G, 3G, 4G, 5G). The packages (e.g., 100) may be configured to support Global System for Mobile (GSM) Communications, Universal Mobile Telecommunications System (UMTS), and/or Long-Term Evolution (LTE). The packages (e.g., 100) may be configured to transmit and receive signals having different frequencies and/or communication protocols.

### Exemplary Sequence for Fabricating a Package

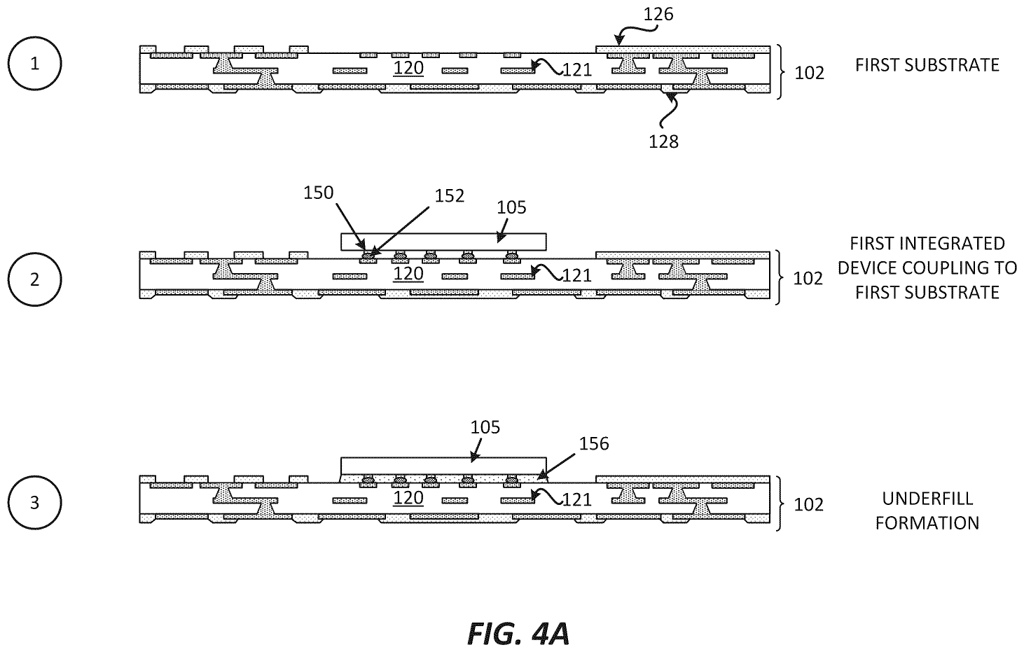

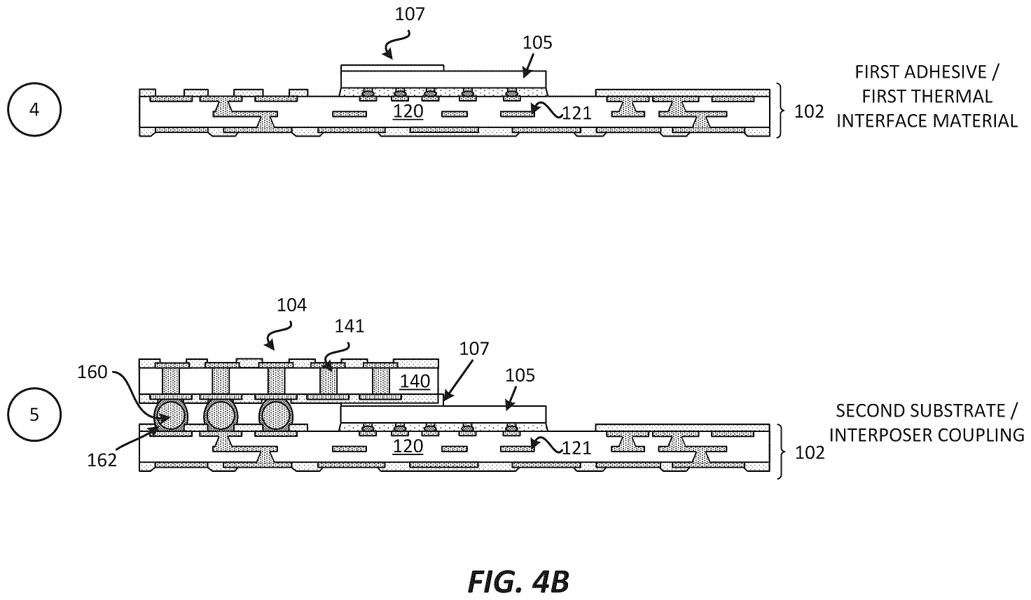

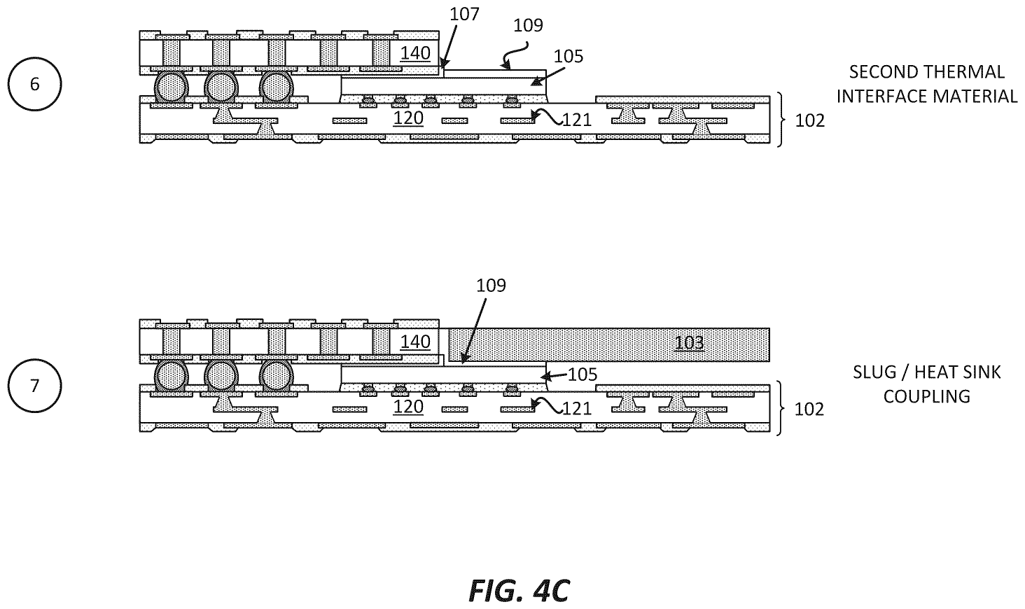

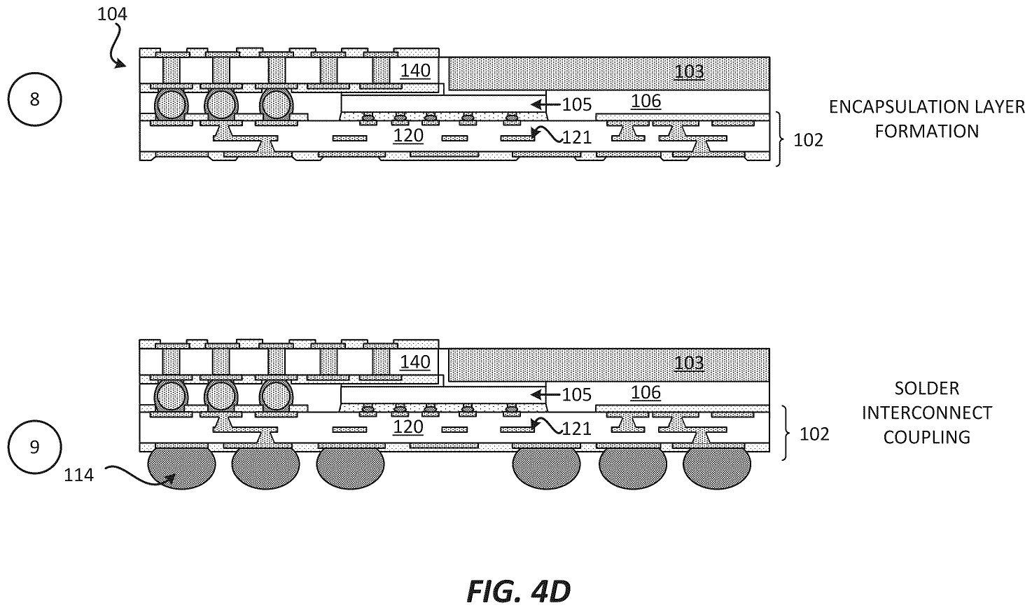

In some implementations, fabricating a package includes several processes. FIGS. 4A-4D illustrate an exemplary sequence for providing or fabricating a package. In some implementations, the sequence of FIGS. 4A-4D may be used to provide or fabricate the package 100. However, the process of FIGS. 4A-4D may be used to fabricate any of the packages described in the disclosure.

It should be noted that the sequence of FIGS. 4A-4D may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

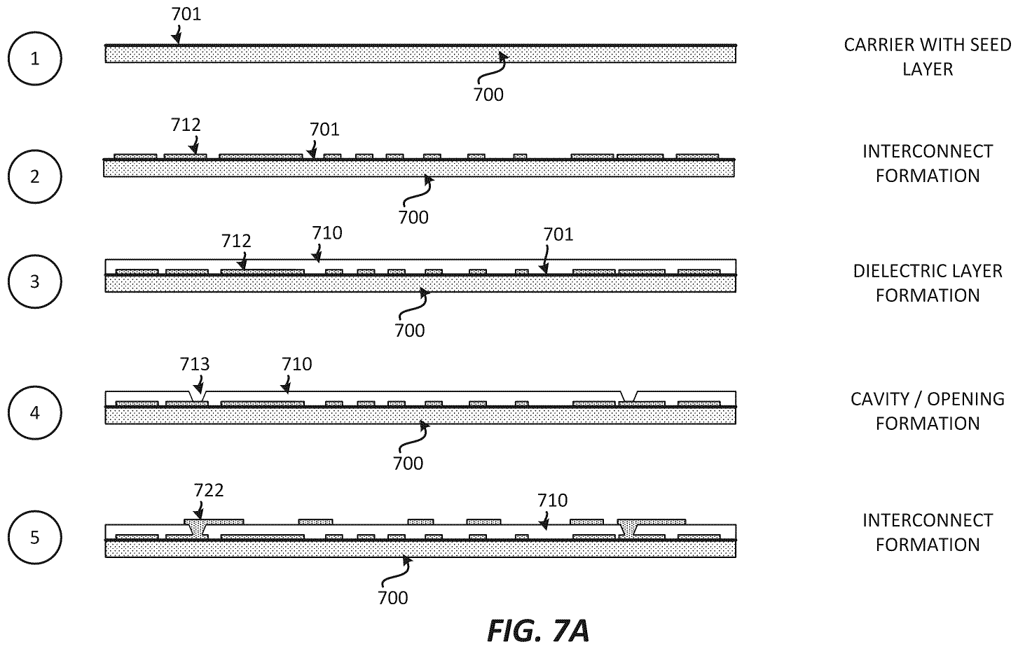

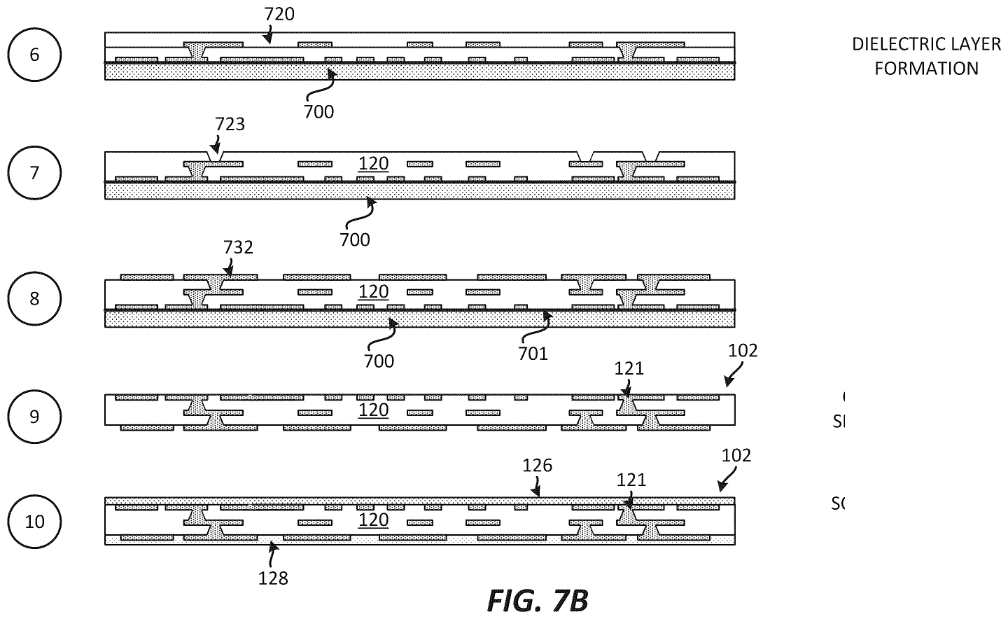

Stage 1, as shown in FIG. 4A, illustrates a state after a substrate 102 is provided. The substrate 102 may be a first substrate. The substrate 102 includes at least one dielectric layer 120, a plurality of interconnects 121, a solder resist layer 126 and a solder resist layer 128. The substrate 102 may include a first surface (e.g., top surface) and a second surface (e.g., bottom surface). The substrate 102 may be fabricated using the method as described below in FIGS. 7A-7B.

Stage 2 illustrates a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102.

Stage 3 illustrates a state after an underfill 156 is formed, dispensed and/or provided. The underfill 156 may be located vertically between the integrated device 105 and the substrate 102. A flow process may be used to provide the underfill 156.

Stage 4, as shown in FIG. 4B, illustrates a state after an adhesive 107 is provided on a portion of the back side of the integrated device 105. The adhesive 107 may be dispended on the back side of the integrated device 105. In some implementations, a thermal interface material (TIM) may be provided on the back side of the integrated device 105.

Stage 5 illustrates a state after the substrate 104 is coupled to the substrate 102 through the plurality of ball interconnects 160 and the plurality of solder interconnects 162. The substrate 104 may also be coupled to the back side of the integrated device 105 through the adhesive 107. A solder reflow process may be used to couple the substrate 104 to the substrate 102. The substrate 104 may be a second substrate. The substrate 104 may be an interposer. The substrate 104 includes a dielectric layer 140 (e.g., interposer dielectric layer) and a plurality of interconnects 141 (e.g., interposer interconnects).

Stage 6, as shown in FIG. 4C, illustrates a state after a thermal interface material (TIM) 109 is provided on a portion of the integrated device 105. The thermal interface material (TIM) 109 may be dispended on at least a portion of the back side of the integrated device 105. In some implementations, the thermal interface material (TIM) 109 may already have been disposed on the back side of the integrated device (e.g., during stage 4). The thermal interface material (TIM) 109 may have better thermal conductivity properties than the adhesive 107. The thermal interface material (TIM) 109 may include a different material from the adhesive 107.

Stage 7 illustrates a state after the heat sink 103 is coupled to the back side of the integrated device 105 through the thermal interface material (TIM) 109. In some implementations, a pick and place process may be used to couple the heat sink 103 to the back side of the integrated device 105. The heat sink 103 may include copper (Cu).

Stage 8, as shown in FIG. 4D, illustrates a state after an encapsulation layer 106 is provided (i) between the substrate 102 and the heat sink 103, and (ii) between the substrate 102 and the substrate 104. The encapsulation layer 106 may include a mold, a resin, an epoxy and/or a filler. The encapsulation layer 106 may include a different material and/or a different composition from the underfill 156. The encapsulation layer 106 may be provided by using a compression and transfer molding process, a sheet molding process, or a liquid molding process.

Stage 9 illustrates a state after a plurality of solder interconnects 114 are coupled to the second surface of the substrate 102. A solder reflow process may be used to couple the plurality of solder interconnects 114 to the substrate 102. The plurality of solder interconnects 114 may be coupled to the plurality of interconnects 121.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Sequence for Fabricating a Package

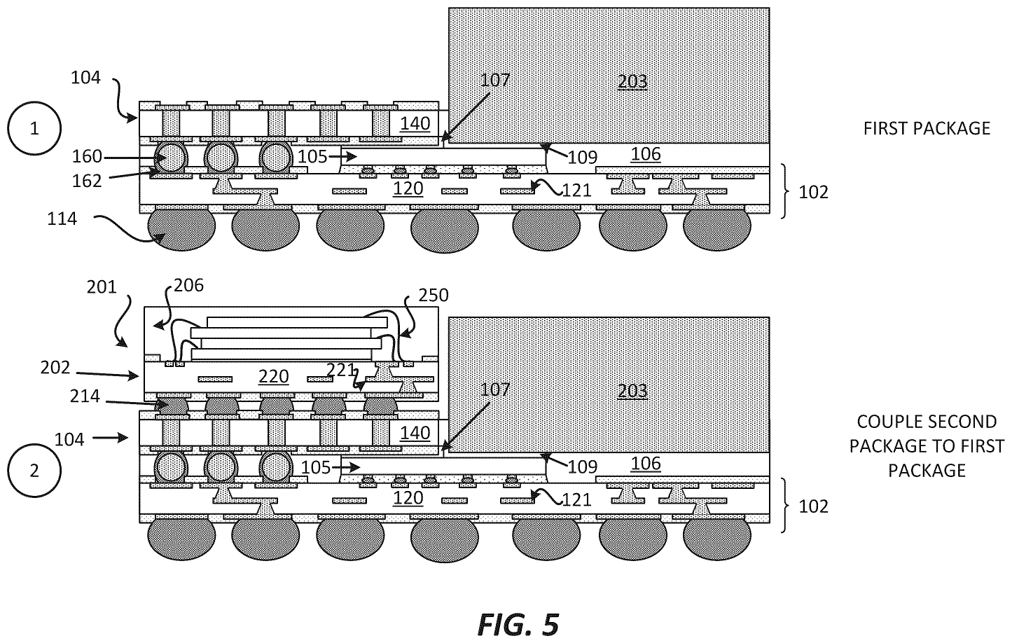

In some implementations, fabricating a package includes several processes. FIG. 5 illustrates an exemplary sequence for providing or fabricating a package. In some implementations, the sequence of FIG. 5 may be used to provide or fabricate the package 200. However, the process of FIG. 5 may be used to fabricate any of the packages described in the disclosure.

It should be noted that the sequence of FIG. 5 may combine one or more stages in order to simplify and/or clarify the sequence for providing or fabricating a package. In some implementations, the order of the processes may be changed or modified. In some implementations, one or more of processes may be replaced or substituted without departing from the scope of the disclosure.

Stage 1, as shown in FIG. 5, illustrates a state after a package that includes a substrate 102, a substrate 104, an encapsulation layer 106 and a heat sink 203, is provided. The substrate 102 may be a first substrate. The substrate 104 may be a second substrate. The substrate 104 may be an interposer. In some implementations, the package may be fabricated using the process illustrated and described in FIGS. 4A-4D.

Stage 2 illustrates a state after a package 201 is coupled to the substrate 104. The package 201 includes a substrate 202, an integrated device 205a, an integrated device 205b, an integrated device 205c, an integrated device 205d and an encapsulation layer 206. The substrate 202 includes at least one dielectric layer 220 and a plurality of interconnects 221. The integrated device 205a, the integrated device 205b, the integrated device 205c and the integrated device 205d may be a stack of integrated devices. The integrated device 205a, the integrated device 205b, the integrated device 205c and the integrated device 205d may each be a memory die (e.g., dynamic random access memory (DRAM) die). The integrated device 205a, the integrated device 205b, the integrated device 205c and/or the integrated device 205d may be configured to be electrically coupled to the substrate 202 through at least one wire bond from a plurality of wire bonds 250. The encapsulation layer 206 is coupled to the substrate 202. The encapsulation layer 206 may at least partially encapsulate the integrated device 205a, the integrated device 205b, the integrated device 205c, the integrated device 205d and the plurality of wire bonds 250.

The package 201 is coupled to the substrate 104 through a plurality of solder interconnects 214. For example, the substrate 202 of the package 201 may be coupled to the substrate 104 through the plurality of solder interconnects 214. A solder reflow process may be used to couple the package 201 to the substrate 104. The package 201 may be located laterally (e.g., at least partially laterally) to the heat sink 203. Stage 2 of FIG. 5 may illustrate an example of the package 200 of FIG. 2.

### Exemplary Flow Diagram of a Method for Fabricating a Package

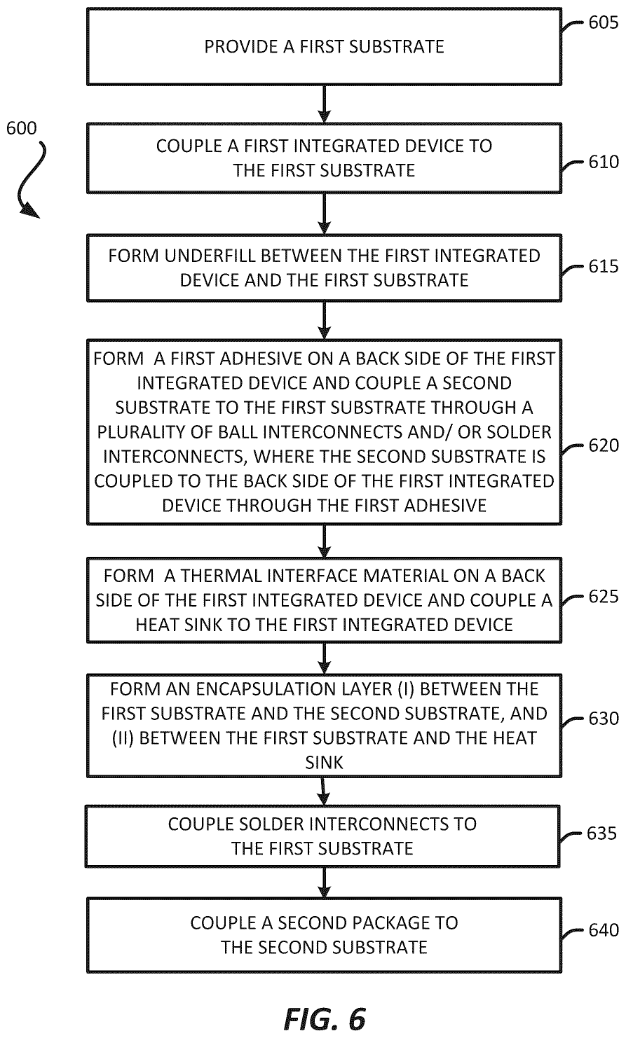

In some implementations, fabricating a package includes several processes. FIG. 6 illustrates an exemplary flow diagram of a method 600 for providing or fabricating a package. In some implementations, the method 600 of FIG. 6 may be used to provide or fabricate the package 100 or the package 200 described in the disclosure. However, the method 600 may be used to provide or fabricate any of the packages described in the disclosure.

It should be noted that the method 600 of FIG. 6 may combine one or more processes in order to simplify and/or clarify the method for providing or fabricating a package. In some implementations, the order of the processes may be changed or modified.

The method provides (at 605) a first substrate. Stage 1 of FIG. 4A, illustrates and describes an example of a state after a substrate 102 is provided. The substrate 102 may be a first substrate. The substrate 102 includes at least one dielectric layer 120, a plurality of interconnects 121, a solder resist layer 126 and a solder resist layer 128. The substrate 102 may include a first surface (e.g., top surface) and a second surface (e.g., bottom surface). The substrate 102 may be fabricated using the method as described in at least FIGS. 7A-7B.

The method couples (at 610) a first integrated device to a first surface of the first substrate. Stage 2 of FIG. 4A, illustrates and describes an example of a state after an integrated device 105 is coupled to the first surface (e.g., top surface) of the substrate 102. The integrated device 105 may be coupled to the substrate 102 through the plurality of pillar interconnects 150 and the plurality of solder interconnects 152. In some implementations, the integrated device 105 may be coupled to the substrate 102 through the plurality of solder interconnects 152. A solder reflow process may be used to couple the integrated device 105 to the substrate 102.

The method forms (at 615) an underfill between the first integrated device and the first substrate. Stage 3 of FIG. 4A, illustrates and describes an example of a state after an underfill 156 is formed, dispensed and/or provided. The underfill 156 may be located vertically between the integrated device 105 and the substrate 102. A flow process may be used to provide the underfill 156.

The method forms and provides (at 620) a first adhesive on a back side of the first integrated device and (i) couples a second substrate to the first substrate through a plurality of ball interconnects and/or a plurality of solder interconnects, and (ii) couples the second substrate to the back side of the first integrated device through the first adhesive. Stage 4 of FIG. 4B, illustrates and describes an example of a state after an adhesive 107 is provided on a portion of the back side of the integrated device 105. The adhesive 107 may be dispended on the back side of the integrated device 105. In some implementations, a thermal interface material (TIM) may be provided on the back side of the integrated device 105. Stage 5 of FIG. 4B, illustrates and describes an example of a state after the substrate 104 is coupled to the substrate 102 through the plurality of ball interconnects 160 and the plurality of solder interconnects 162. The substrate 104 may also be coupled to the back side of the integrated device 105 through the adhesive 107. A solder reflow process may be used to couple the substrate 104 to the substrate 102. The substrate 104 may be a second substrate. The substrate 104 may be an interposer. The substrate 104 includes a dielectric layer 140 (e.g., interposer dielectric layer) and a plurality of interconnects 141 (e.g., interposer interconnects).

The method forms and provides (at 625) a thermal interface material (TIM) on a back side of the first integrated device and couples a heat sink to the back side of the first integrated device through the thermal interface material (TIM). Stage 6 of FIG. 4C, illustrates and describes an example of a state after a thermal interface material (TIM) 109 is provided on a portion of the back side of the integrated device 105. The thermal interface material (TIM) 109 may be dispended on the back side of the integrated device 105. In some implementations, the thermal interface material (TIM) 109 may already have been disposed on the back side of the integrated device (e.g., during stage 4). The thermal interface material (TIM) 109 may have better thermal conductivity properties than the adhesive 107. Stage 7 of FIG. 4C, illustrates and describes an example of a state after the heat sink 103 is coupled to the back side of the integrated device 105 through the thermal interface material (TIM) 109. In some implementations, a pick and place process may be used to couple the heat sink 103 to the back side of the integrated device 105.

The method forms (at 630) an encapsulation layer (i) between the first substrate and the heat sink, and (ii) between the first substrate and the second substrate. Stage 8 of FIG. 4D, illustrates and describes an example of a state after an encapsulation layer 106 is provided (i) between the substrate 102 and the heat sink 103, and (ii) between the substrate 102 and the substrate 104. The encapsulation layer 106 may include a mold, a resin, an epoxy and/or a filler. The encapsulation layer 106 may include a different material and/or a different composition from the underfill 156. The encapsulation layer 106 may be provided by using a compression and transfer molding process, a sheet molding process, or a liquid molding process.

The method couples (at 635) a plurality of solder interconnects to the first substrate. Stage 9 of FIG. 4D, illustrates and describes an example of a state after a plurality of solder interconnects 114 are coupled to the second surface of the substrate 102. A solder reflow process may be used to couple the plurality of solder interconnects 114 to the substrate 102.

The method couples (at 640) a package to the second substrate. The package may be coupled to the second substrate through a plurality of solder interconnects. Stage 2 of FIG. 5, illustrates and describes an example of a state after a package 201 is coupled to the substrate 104. The package 201 includes a substrate 202, an integrated device 205a, an integrated device 205b, an integrated device 205c, an integrated device 205d and an encapsulation layer 206. The substrate 202 includes at least one dielectric layer 220 and a plurality of interconnects 221. The integrated device 205a, the integrated device 205b, the integrated device 205c and the integrated device 205d may be a stack of integrated devices. The integrated device 205a, the integrated device 205b, the integrated device 205c and the integrated device 205d may each be a memory die (e.g., dynamic random access memory (DRAM) die). The integrated device 205a, the integrated device 205b, the integrated device 205c and/or the integrated device 205d may be configured to be electrically coupled to the substrate 202 through a plurality of wire bonds. The encapsulation layer 206 is coupled to the substrate 202. The encapsulation layer 206 may at least partially encapsulate the integrated device 205a, the integrated device 205b, the integrated device 205c and the integrated device 205d.

The package 201 is coupled to the substrate 104 through a plurality of solder interconnects 214. For example, the substrate 202 may be coupled to the substrate 104 through the plurality of solder interconnects 214. A solder reflow process may be used to couple the package 201 to the substrate 104. The package 201 may be located laterally (e.g., at least partially laterally) to the heat sink 203. Stage 2 of FIG. 5 may illustrate an example of the package 200 of FIG. 2.

### Exemplary Sequence for Fabricating a Substrate

In some implementations, fabricating a substrate includes several processes. FIGS. 7A-7B illustrate an exemplary sequence for providing or fabricating a substrate. In some implementations, the sequence of FIGS. 7A-7B may be used to provide or fabricate the substrate 102. However, the process of FIGS. 7A-7B may be used to fabricate any of the substrates described in the disclosure.

It should be noted that the sequence of FIGS. 7A-7B may combine one or more stages in order to simplify and/or clarify the sequence for providing or fabricating a substrate. In some implementations, the order of the processes may be changed or modified. In some implementations, one or more of processes may be replaced or substituted without departing from the scope of the disclosure.

Stage 1, as shown in FIG. 7A, illustrates a state after a carrier 700 is provided. A seed layer 701 may be located over the carrier 700.

Stage 2 illustrates a state after a plurality of interconnects 712 are formed. The interconnects 712 may be located over the seed layer 701. A lithography process, a plating process, a strip process and/or an etching process may be used to form the plurality of interconnects 712. The interconnects 712 may represent at least some of the interconnects from the plurality of interconnects 121.

Stage 3 illustrates a state after a dielectric layer 710 is formed over the carrier 700, the seed layer 701 and the plurality of interconnects 712. A deposition and/or lamination process may be used to form the dielectric layer 710. The dielectric layer 710 may include prepreg and/or polyimide. The dielectric layer 710 may include a photo-imageable dielectric. However, different implementations may use different materials for the dielectric layer.

Stage 4 illustrates a state after a plurality of cavities 713 is formed in the dielectric layer 710. The plurality of cavities 713 may be formed using an etching process (e.g., photo etching process), a laser process, an exposure process and/or a development process.

Stage 5 illustrates a state after interconnects 722 are formed in and over the dielectric layer 710, including in and over the plurality of cavities 713. For example, a via, pad and/or traces may be formed. A lithography process, a plating process, a strip process and/or an etching process may be used to form the interconnects.

Stage 6, as shown in FIG. 7B, illustrates a state after a dielectric layer 720 is formed over the dielectric layer 710 and the plurality of interconnects 722. A deposition and/or lamination process may be used to form the dielectric layer 720. The dielectric layer 720 may include prepreg and/or polyimide. The dielectric layer 720 may include a photo-imageable dielectric. However, different implementations may use different materials for the dielectric layer.

Stage 7, illustrates a state after a plurality of cavities 723 is formed in the dielectric layer 120. The dielectric layer 120 may represent the dielectric layer 710 and/or the dielectric layer 720. The plurality of cavities 723 may be formed using an etching process (e.g., photo etching process), a laser process, an exposure process and/or a development process.

Stage 8 illustrates a state after interconnects 732 are formed in and over the dielectric layer 140, including in and over the plurality of cavities 723. For example, a via, pad and/or traces may be formed. A lithography process, a plating process, a strip process and/or an etching process may be used to form the interconnects.

Stage 9 illustrates a state after the carrier 700 is decoupled (e.g., detached, removed, grinded out) from at least one dielectric layer 120 and the seed layer 701, portions of the seed layer 701 are removed (e.g., etched out), leaving the substrate 102 that includes at least one dielectric layer 120 and the plurality of interconnects 121. The plurality of interconnects 121 may represent the plurality of interconnects 712, the plurality of interconnects 722 and/or the plurality of interconnects 732.

Stage 10 illustrates a state after the solder resist layer 126 is formed over the first surface of the substrate 102, and after the solder resist layer 128 is formed over the second surface of the substrate 102. A deposition process and/or lamination process may be used to form the solder resist layer 126 and/or the solder resist layer 128. The solder resist layer 126 and/or the solder resist layer 128 may include openings. An etching process, an exposure process and/or a development process may be used to form the openings in the solder resist layer 126 and/or the openings in the solder resist layer 128.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Substrate

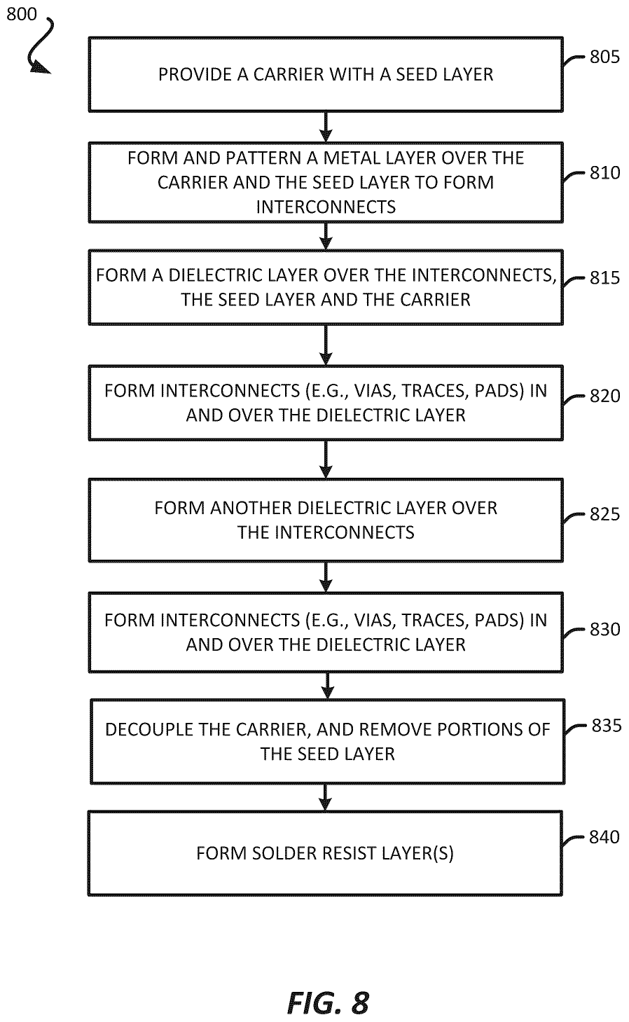

In some implementations, fabricating a substrate includes several processes. FIG. 8 illustrates an exemplary flow diagram of a method 800 for providing or fabricating a substrate. In some implementations, the method 800 of FIG. 8 may be used to provide or fabricate the substrate(s) of the disclosure. For example, the method 800 of FIG. 8 may be used to fabricate the substrate 102.

It should be noted that the method 800 of FIG. 8 may combine one or more processes in order to simplify and/or clarify the method for providing or fabricating a substrate. In some implementations, the order of the processes may be changed or modified.

The method provides (at 805) a carrier with a seed layer. Stage 1 of FIG. 7A, illustrates and describes an example of a state after a carrier 700 is provided. A seed layer 701 may be located over the carrier 700.

The method forms and patterns (at 810) a plurality of interconnects. Stage 2 of FIG. 7A, illustrates and describes an example of a state after a plurality of interconnects 712 are formed. The interconnects 712 may be located over the seed layer 701. A lithography process, a plating process, a strip process and/or an etching process may be used to form the plurality of interconnects 712. The interconnects 712 may represent at least some of the interconnects from the plurality of interconnects 121.

The method forms (at 815) a dielectric layer. Stage 3 of FIG. 7A, illustrates and describes an example of a state after a dielectric layer 710 is formed over the carrier 700, the seed layer 701 and the plurality of interconnects 712. A deposition and/or lamination process may be used to form the dielectric layer 710. The dielectric layer 710 may include prepreg and/or polyimide. The dielectric layer 710 may include a photo-imageable dielectric. However, different implementations may use different materials for the dielectric layer.

The method forms (at 820) a plurality of interconnects. Forming a plurality of interconnects may including forming a plurality of cavities in a dielectric layer and a performing a plating process. Stage 4 of FIG. 7A, illustrates and describes an example of a state after a plurality of cavities 713 is formed in the dielectric layer 710. The plurality of cavities 713 may be formed using an etching process (e.g., photo etching process), a laser process, an exposure process and/or a development process.

Stage 5 of FIG. 7A, illustrates and describes an example of a state after interconnects 722 are formed in and over the dielectric layer 710, including in and over the plurality of cavities 713. For example, a via, pad and/or traces may be formed. A lithography process, a plating process, a strip process and/or an etching process may be used to form the interconnects.

The method forms (at 825) another dielectric layer. Stage 6 of FIG. 7B, illustrates and describes an example of a state after a dielectric layer 720 is formed over the dielectric layer 710 and the plurality of interconnects 722. A deposition and/or lamination process may be used to form the dielectric layer 720. The dielectric layer 720 may include prepreg and/or polyimide. The dielectric layer 720 may include a photo-imageable dielectric. However, different implementations may use different materials for the dielectric layer.

The method forms (at 830) a plurality of interconnects. Forming a plurality of interconnects may including forming a plurality of cavities in a dielectric layer and a performing a plating process. Stage 7 of FIG. 7B, illustrates and describes an example of a state after a plurality of cavities 723 is formed in the dielectric layer 120. The dielectric layer 120 may represent the dielectric layer 710 and/or the dielectric layer 720. The plurality of cavities 723 may be formed using an etching process (e.g., photo etching process), a laser process, an exposure process and/or a development process.

Stage 8 of FIG. 7B, illustrates and describes an example of a state after interconnects 732 are formed in and over the dielectric layer 120, including in and over the plurality of cavities 723. For example, a via, pad and/or traces may be formed. A lithography process, a plating process, a strip process and/or an etching process may be used to form the interconnects.

The method decouples (at 835) a carrier. Stage 9 of FIG. 7B, illustrates and describes an example of a state after the carrier 700 is decoupled (e.g., detached, removed, grinded out) from at least one dielectric layer 120 and the seed layer 701, portions of the seed layer 701 are removed (e.g., etched out), leaving the substrate 102 that includes at least one dielectric layer 120 and the plurality of interconnects 121. The plurality of interconnects 121 may represent the plurality of interconnects 712, the plurality of interconnects 722 and/or the plurality of interconnects 732.

The method forms (at 840) solder resist layers. Stage 10 of FIG. 7B, illustrates and describes an example of a state after the solder resist layer 126 is formed over the first surface of the substrate 102, and after the solder resist layer 128 is formed over the second surface of the substrate 102. A deposition process and/or lamination process may be used to form the solder resist layer 126 and/or the solder resist layer 128. An etching process, an exposure process and/or a development process may be used to form the openings in the solder resist layer 126 and/or the openings in the solder resist layer 128.

Different implementations may use different processes for forming the metal layer(s) and/or interconnects. In some implementations, a chemical vapor deposition (CVD) process, a physical vapor deposition (PVD) process, a sputtering process, a spray coating process, and/or a plating process may be used to form the metal layer(s).

### Exemplary Flow Diagram of a Method for Fabricating a Package

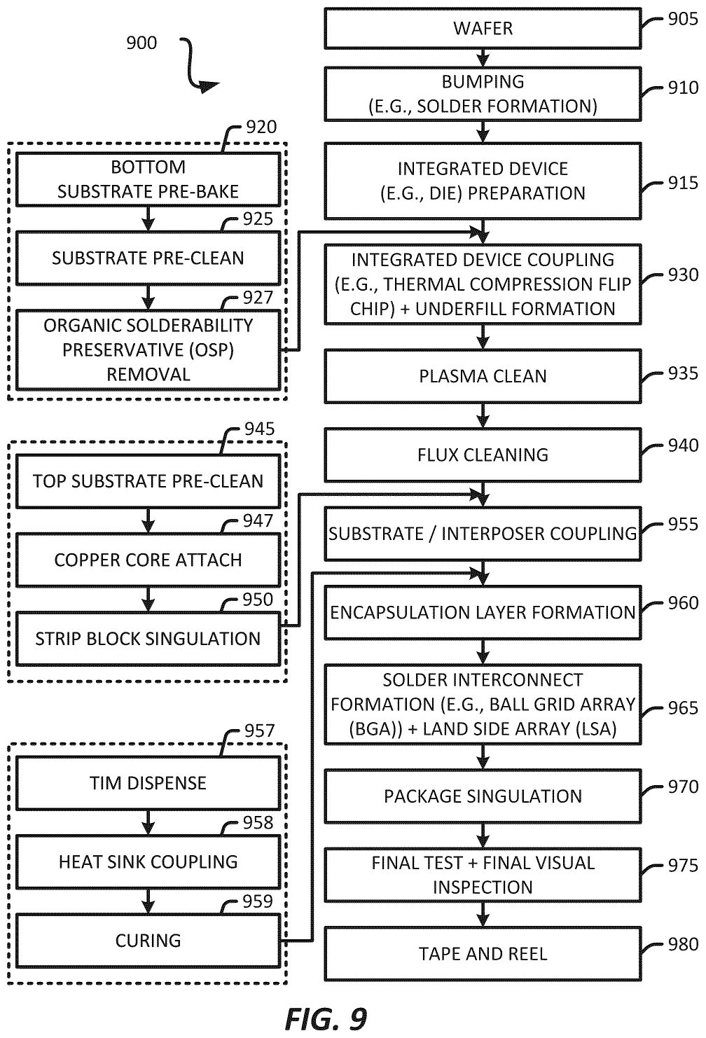

FIG. 9 illustrates an exemplary flow diagram of a method 900 for providing or fabricating a package. In some implementations, the method 900 of FIG. 9 may be used to provide or fabricate some or all of the package 100 of FIG. 1 described in the disclosure. However, the method 900 may be used to provide or fabricate any of the packages described in the disclosure.

It should be noted that the method 900 of FIG. 9 may combine one or more processes in order to simplify and/or clarify the method for providing or fabricating a package. In some implementations, the order of the processes may be changed or modified.

The method provides (at 905) a wafer. The wafer may serve as a substrate on which integrated devices may be formed and/or coupled to. In some implementations, other substrates may be coupled to the wafer. The wafer may include silicon. The wafer may serve as a base on which components are built over.

The method forms (at 910) solder interconnects on the wafer. A solder reflow process may be used to form (e.g., couple) solder interconnects on the wafer.

The method prepares (at 915) one or more integrated devices (e.g., dies) for coupling. Preparing the integrated devices may include fabricating the integrated devices.

The method provides and prepares (at 920) a first substrate (e.g., substrate 102, bottom substrate) by pre-baking the first substrate. The first substrate may be pre-baked to remove moisture on the first substrate to avoid outgassing during a subsequent thermal compression flip chip coupling process. The method pre-cleans (at 925) the first substrate. The method removes (at 927) organic solderability preservative (OSP) on the first substrate. Stage 1 of FIG. 4A, illustrates and describes an example of a first substrate that is provided.

Once the first substrate is provided and prepared, the first substrate may be coupled to the wafer through the solder interconnects that are formed on the wafer.

The integrated device(s) is/are coupled (at 930) to the first substrate. For example, the integrated device 105 may be coupled to the substrate 102 through a thermal compression flip chip process. An underfill may be provided between the integrated device and the substrate. Stages 2 and 3 of FIG. 4A illustrate and describe an example of an integrated device that is coupled to a substrate and an underfill that is provided between the integrated device and the substrate.

The method performs (at 935) a plasma clean of the first substrate. The plasma clean may remove contamination on the surface of the substrate.

The method performs (at 940) a flux cleaning of one or more substrates. Flux cleaning may remove oxides from metal of the substrate. The flux cleaning may be performed on the first substrate and/or the second substrate.

The method pre-cleans (at 945) a second substrate (e.g., substrate 104, top substrate). The method couples (at 947) ball interconnects (e.g., copper core ball) to the second substrate. The ball interconnects may be coupled to the substrate 104 through solder interconnects (e.g., 160). A solder reflow process may be used to couple the ball interconnects to the second substrate. The method performs (at 950) strip block singulation of the second substrate. This may be done, when several substrates are fabricated at the same time and then subsequently singulated.

The method couples (at 955) the second substrate (e.g., 104) to the first substrate (e.g., 102) through the ball interconnects. A solder reflow process may be used to couple the second substrate to the first substrate. In some implementations, before the second substrate is coupled to the first substrate, an adhesive (e.g., 107) or a thermal interface material (TIM) (e.g., 109) is dispensed over the back side of the integrated device. Stage 4 of FIG. 4B, illustrates and describes an example of providing an adhesive to the back side of an integrated device. Stage 5 of FIG. 4B, illustrates and describes an example of a second substrate that is provided and coupled to the first substrate through ball interconnects and/or solder interconnects.

The method dispenses (at 957) a thermal interface material (TIM) (e.g., 109) on the back side of an integrated device (e.g., 105). Stage 6 of FIG. 4C, illustrates and describes an example of providing a thermal interface material (TIM) on the back side of an integrated device. The method couples (at 958) a heat sink (e.g., 103, 203) to the back side of the integrated device (e.g., 105). The heat sink may be coupled to the back side of the integrated device through the thermal interface material (TIM). Stage 7 of FIG. 4C, illustrates and describes an example of coupling a heat sink to the back side of an integrated device. The method cures (at 959) the thermal interface material (TIM).

The method provides (at 960) an encapsulation layer (e.g., 106) between the first substrate and the second substrate. The encapsulation layer may also be provided between the first substrate and the heat sink. Stage 8 of FIG. 4D, illustrates and describes an example of providing an encapsulation layer between substrates, and between a first substrate and a heat sink.

The method forms (at 965) solder interconnects or land side array (LSA) on the first substrate. A solder reflow process may be used to form the solder interconnects. The solder interconnects may be a ball grid array (BGA). Stage 9 of FIG. 4D, illustrates and describes an example of coupling a plurality of solder interconnects to a first substrate.

The method singulates (at 970) the packages into individual packages. This may occur when several packages are fabricated at the same time. Singulating the package may include singulating the wafer that includes the first substrates, the integrated device(s), and the second substrates. A mechanical process (e.g., saw) or a laser may be used to singulate the packages.

The method performs (at 975) a final test and final visual inspection of the package. This may include testing whether the package works properly by attaching probes to the package to determine whether the package works as intended. Visual inspection may include visually inspecting to see whether the package has any defects.

The method performs (at 980) tape and reel of the packages. This may include packaging the singulated packages together with tape so that the package can be properly shipped.

It is noted that additional processes may be performed on the packages, including coupling other components, such as passive components and/or integrated devices to the packages. FIG. 9 illustrates an example of how packages may be fabricated. FIG. 9 is not intended to illustrate the only way that a package may be fabricated.

### Exemplary Electronic Devices

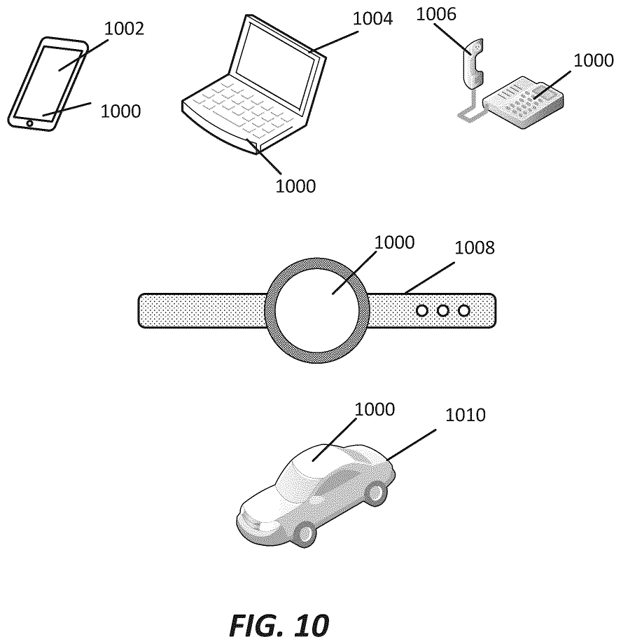

FIG. 10 illustrates various electronic devices that may be integrated with any of the aforementioned device, integrated device, integrated circuit (IC) package, integrated circuit (IC) device, semiconductor device, integrated circuit, die, interposer, package, package-on-package (POP), System in Package (SiP), or System on Chip (SoC). For example, a mobile phone device 1002, a laptop computer device 1004, a fixed location terminal device 1006, a wearable device 1008, or automotive vehicle 1010 may include a device 1000 as described herein. The device 1000 may be, for example, any of the devices and/or integrated circuit (IC) packages described herein. The devices 1002, 1004, 1006 and 1008 and the vehicle 1010 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-3, 4A-4D, 5, 6, 7A-7B, and 8-10 may be rearranged and/or combined into a single component, process, feature or function or embodied in several components, processes, or functions. Additional elements, components, processes, and/or functions may also be added without departing from the disclosure. It should also be noted FIGS. 1-3, 4A-4D, 5, 6, 7A-7B, and 8-10 and its corresponding description in the present disclosure is not limited to dies and/or ICs. In some implementations, FIGS. 1-3, 4A-4D, 5, 6, 7A-7B, and 8-10 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.

Aspect 1: A package comprising a first substrate; an integrated device coupled to the first substrate; a second substrate coupled to the first substrate through at least a plurality of solder interconnects, wherein the second substrate is located over a portion of the integrated device; and a heat sink coupled to a back side of the integrated device through a thermal interface material, wherein the heat sink is located over another portion of the integrated device, wherein the heat sink is located laterally to the second substrate.

Aspect 2: The package of aspect 1, further comprising an encapsulation layer located between the first substrate and the second substrate.

Aspect 3: The package of aspect 2, wherein the encapsulation layer is further located between the first substrate and the heat sink.

Aspect 4: The package of aspects 1 through 3, wherein the second substrate is coupled to the back side of the integrated device through the thermal interface material.

Aspect 5: The package of aspects 1 through 3, wherein the second substrate is coupled to the back side of the integrated device through another thermal interface material.

Aspect 6: The package of aspects 1 through 3, wherein the second substrate is coupled to the back side of the integrated device through an adhesive.

Aspect 7: The package of aspects 1 through 6, wherein the second substrate is coupled to the first substrate through a plurality of ball interconnects and/or the plurality of solder interconnects.

Aspect 8: The package of aspects 1 through 7, further comprising an underfill located between the integrated device and the first substrate.

Aspect 9: The package of aspect 8, wherein the underfill includes a different material or a different composition from an encapsulation layer located between the first substrate and the second substrate.

Aspect 10: The package of aspects 1 through 9, wherein the heat sink includes a metal slug.

Aspect 11: The package of aspects 1 through 10, wherein the second substrate is an interposer.

Aspect 12: The package of aspect 11, wherein the interposer comprises an interposer dielectric layer; and a plurality of interposer interconnects.

Aspect 13: The package of aspect 12, wherein the interposer dielectric layer includes silicon, glass or an organic dielectric layer.

Aspect 14: The package of aspects 1 through 13, further comprising another package coupled to the second substrate, wherein the another package comprises a package substrate; and a second integrated device coupled to the package substrate.

Aspect 15: The package of aspect 14, wherein the second integrated device is configured to be electrically coupled to the package substrate through a plurality of wire bonds.

Aspect 16: The package of aspect 14, wherein the another package further comprises a package encapsulation layer.

Aspect 17: The package of aspect 14, wherein the another package is located laterally to the heat sink.

Aspect 18: The package of aspects 1 through 13, further comprising a second integrated device coupled to the second substrate through a second plurality of solder interconnects.

Aspect 19: The package of aspects 1 through 18, further comprising another package coupled to the second substrate through a second plurality of solder interconnects.

Aspect 20: The package of aspects 1 through 19, wherein the integrated device is coupled to the first substrate through a plurality of pillar interconnects and/or a first plurality of solder interconnects.

Aspect 21: The package of aspects 1 through 20, wherein the package is implemented in a device consisting of one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

Aspect 22: A device comprising the package of aspects 1 through 20, wherein the device is one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A package comprising:
a first substrate;
an integrated device coupled to the first substrate;
a second substrate coupled to the first substrate through at least a plurality of solder interconnects, wherein the second substrate is located over a portion of the integrated device; and
a heat sink coupled to a back side of the integrated device through a thermal interface material, wherein the heat sink is located over another portion of the integrated device, wherein the heat sink is located laterally to the second substrate.

2. The package of claim 1, further comprising an encapsulation layer located between the first substrate and the second substrate.

3. The package of claim 2, wherein the encapsulation layer is further located between the first substrate and the heat sink.

4. The package of claim 1, wherein the second substrate is coupled to the back side of the integrated device through the thermal interface material.

5. The package of claim 1, wherein the second substrate is coupled to the back side of the integrated device through another thermal interface material.

6. The package of claim 1, wherein the second substrate is coupled to the back side of the integrated device through an adhesive.

7. The package of claim 1, wherein the second substrate is coupled to the first substrate through a plurality of ball interconnects and/or the plurality of solder interconnects.

8. The package of claim 1, further comprising an underfill located between the integrated device and the first substrate.

9. The package of claim 8, wherein the underfill includes a different material or a different composition from an encapsulation layer located between the first substrate and the second substrate.

10. The package of claim 1, wherein the heat sink includes a metal slug.

11. The package of claim 1, wherein the second substrate is an interposer.

12. The package of claim 11, wherein the interposer comprises:
an interposer dielectric layer; and
a plurality of interposer interconnects.

13. The package of claim 12, wherein the interposer dielectric layer includes silicon, glass or an organic dielectric layer.

14. The package of claim 1, further comprising another package coupled to the second substrate, wherein the another package comprises:
a package substrate; and
a second integrated device coupled to the package substrate.

15. The package of claim 14, wherein the second integrated device is configured to be electrically coupled to the package substrate through a plurality of wire bonds.

16. The package of claim 14, wherein the another package further comprises a package encapsulation layer.

17. The package of claim 14, wherein the another package is located laterally to the heat sink.

18. The package of claim 1, further comprising a second integrated device coupled to the second substrate through a second plurality of solder interconnects.

19. The package of claim 1, further comprising another package coupled to the second substrate through a second plurality of solder interconnects.

20. The package of claim 1, wherein the integrated device is coupled to the first substrate through a plurality of pillar interconnects and/or a first plurality of solder interconnects.
